(19) United States
(12) Patent Application Publication
(10) Pub. No.: US 2005/0212024 A1
(43) Pub. Date: Sep. 29, 2005

(54) Memory device with an active material embedded in an insulating material

(75) Inventor: Thomas Happ, Pleasantville, NY (US)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 11/086,997

(22) Filed: Mar. 23, 2005

(30) Foreign Application Priority Data
Mar. 24, 2004 (DE) 10 2004 014 487.7

(51) Int. Cl. H01L 21/8234; H01L 21/8244; H01L 27/108; H01L 31/119; H01L 29/76; H01L 29/94

(52) U.S. Cl. 257/296

(57) ABSTRACT

The invention relates to a method for producing a memory device, and to a memory device having an active material adapted to be placed in a more or less conductive state by means of appropriate switching processes, the active material is embedded in electrically insulating material.

### CLAIM FOR PRIORITY

This application claims priority to German Application No. 10 2004 014 487.7, filed Mar. 24, 2004, which is incorporated herein, in its entirety, by reference.

### TECHNICAL FIELD OF THE INVENTION

The invention relates to a memory device and to a method for producing a memory device.

### BACKGROUND OF THE INVENTION

In the case of conventional memory devices, in particular conventional semiconductor memory devices, one differentiates between so-called functional memory devices (e.g. PLAs, PALs, etc.) and so-called table memory devices, e.g. ROM devices (ROM=Read Only Memory)—in particular PROMs, EPROMs, EEPROMs, flash memories, etc.—, and RAM devices (RAM=Random Access Memory or read-write memory), e.g. DRAMs and SRAMs.

A RAM device is a memory for storing data under a predetermined address and for reading out the data under this address later.

Since it is intended to accommodate as many memory cells as possible in a RAM device, one has been trying to realize same as simple as possible.

In the case of SRAMs (SRAM=Static Random Access Memory), the individual memory cells consist e.g. of few, for instance 6, transistors, and in the case of so-called DRAMs (DRAM=Dynamic Random Access Memory) in general only of one single, correspondingly controlled capacitive element (e.g. the gate-source capacitance of a MOSFET), with the capacitance of which one bit each can be stored as charge.

This charge, however, remains for a short time only. Therefore, a so-called “refresh” must be performed regularly, e.g. approximately every 64 ms.

In contrast to that, no “refresh” has to be performed in the case of SRAMS, i.e. the data stored in the memory cell remain stored as long as an appropriate supply voltage is fed to the SRAM.

In the case of non-volatile memory devices (NVMs), e.g. EPROMs, EEPROMs, and flash memories, the stored data remain, however, stored even when the supply voltage is switched off.

Furthermore, so-called “resistive” or “resistively switching” memory devices have also become known recently, e.g. so-called Phase Change Memories, etc.

In the case of “resistive” or “resistively switching” memory devices, a material—which is, for instance, positioned between two appropriate electrodes (i.e. an anode and a cathode)—is placed, by appropriate switching processes, in a more or less conductive state (wherein e.g. the more conductive state corresponds to a stored, logic “One”, and the less conductive state corresponds to a stored, logic “Zero”, or vice versa).

In the case of Phase Change Memories, an appropriate chalcogenide compound (e.g. a Ge—Sb—Te or an Ag—In—Sb—Te compound) may, for instance, be used as an “active” material that is positioned between two corresponding electrodes.

The chalcogenide compound material can be placed in an amorphous, i.e. relatively weakly conductive, or a crystalline, i.e. relatively strongly conductive state by means of appropriate switching processes (wherein e.g. the relatively strongly conductive state may again correspond to a stored, logic “One”, and the relatively weakly conductive state may correspond to a stored, logic “Zero”, or vice versa).

Phase Change Memories are, for instance, known from G. Wicker, Nonvolatile, High Density, High Performance Phase Change Memory, SPIE Conference on Electronics and Structures for MEMS, Vol. 3891, Queensland, 2, 1999, and e.g. from Y. N. Hwang et al., Completely CMOS Compatible Phase Change Nonvolatile RAM Using NMOS Cell Transistors, IEEE Proceedings of the Nonvolatile Semiconductor Memory Workshop, Monterey, 91, 2003, S. Lai et al., OUM-a 180 nm nonvolatile memory cell element technology for stand alone and embedded applications, IEDM 2001, etc.

In order to achieve, with a corresponding memory cell, a change from an amorphous, i.e. a relatively weakly conductive state of the “active” material, to a crystalline, i.e. relatively strongly conductive state, an appropriate heating current pulse can be applied to the electrodes, said heating current pulse leading to the “active” material being heated beyond the crystallization temperature and crystallizing (“writing process”).

A change of state of the “active” material form a crystalline, i.e. relatively strongly conductive state, to an amorphous, i.e. relatively weakly conductive state, may, for instance, be achieved by—again by means of an appropriate heating current pulse—the “active” material being heated beyond the melting temperature and being “quenched” to an amorphous state by quick cooling (“deleting process”).

To achieve a correspondingly quick heating of the active material beyond the crystallization or melting temperature, respectively, relatively high currents may be necessary, which may result in a correspondingly high power consumption.

Furthermore, the consequence of high heating currents may be that the corresponding cell can no longer be controlled by an individual transistor with a correspondingly small structure size, which may result in a corresponding—possibly strongly reduced—compactness of the respective memory device.

### SUMMARY OF THE INVENTION

The invention provides a memory device and a method for producing a memory device.

In one embodiment of the invention, there is a memory device which comprises an active material that is adapted to be placed in a more or less conductive state by means of appropriate switching processes, the active material is embedded into electrically insulating material.

Advantageously, the active material is completely surrounded by electrically insulating material in the lateral direction.

The active material preferably has a width and/or a length that is smaller than or equal to 100 nm, in particular smaller than or equal to 60 nm, or smaller than or equal to 30 nm.

Due to the focused current flow achieved by the embedding of the active material into the insulating material (and thus the reduction or prevention of parasitic currents occurring outside the melting or crystallization region of the active material), the active material can be heated beyond the crystallization or melting temperature with partially distinctly lower heating currents than in prior art.

### BRIEF DESCRIPTION OF THE DRAWINGS

In the following, the invention will be explained in detail by means of several embodiments and the enclosed drawings. The drawings show:

FIG. 1 shows the structure of a resistively switching memory cell according to prior art.

FIG. 2a shows resistively switching memory cells according to an embodiment of the present invention during a first phase of the production of the memory cells.

FIG. 2b shows the resistively switching memory cells illustrated in FIG. 2a during a second phase of the production of the memory cells.

FIG. 2c shows the resistively switching memory cells illustrated in FIGS. 2a and 2b during a third phase of the production of the memory cells.

FIG. 2d shows the resistively switching memory cells illustrated in FIGS. 2a-2c during a fourth phase of the production of the memory cells.

FIG. 2e shows the resistively switching memory cells illustrated in FIGS. 2a-2d during a fifth phase of the production of the memory cells.

FIG. 2f shows the resistively switching memory cells illustrated in FIGS. 2a-2e during a sixth phase of the production of the memory cells.

FIG. 2g shows the resistively switching memory cells illustrated in FIGS. 2a-2f during a seventh phase of the production of the memory cells.

FIG. 2h shows the resistively switching memory cells illustrated in FIGS. 2a-2g during an eighth phase of the production of the memory cells.

FIG. 3 shows the finished memory cell.

FIG. 4 shows resistively switching memory cells according to a further, alternative embodiment of the present invention, during a first phase of the production of the memory cells—corresponding to the phase illustrated in FIG. 2a.

### DETAILED DESCRIPTION OF THE INVENTION

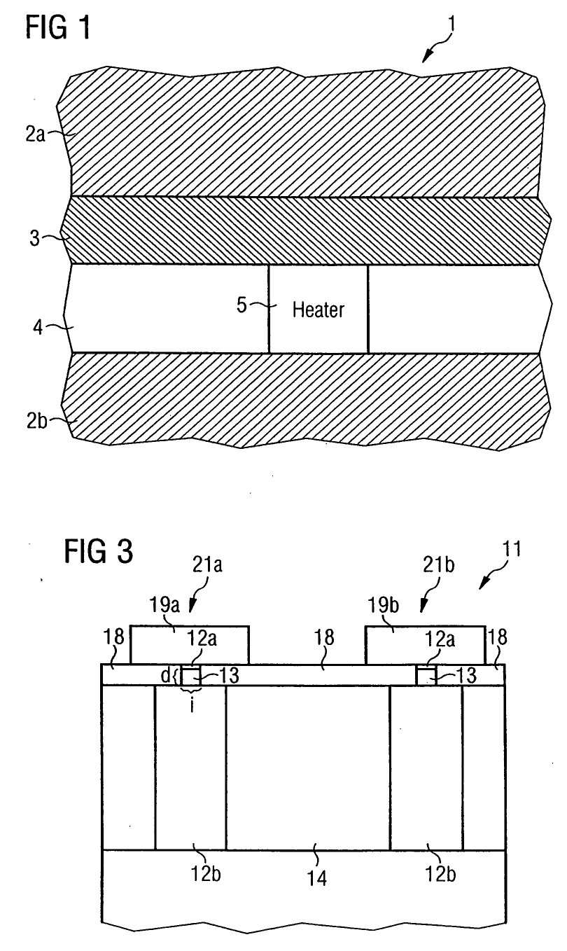

FIG. 1 shows—purely schematically and for the sake of example—the structure of a resistively switching memory cell 1 (here: a Phase Change Memory Cell 1) according to prior art.

It comprises two corresponding metal electrodes 2a, 2b (i.e. one anode and one cathode) between which a corresponding, “active” material layer 3 is positioned which can be placed in a more or less conductive state by means of appropriate switching processes (wherein e.g. the more conductive state corresponds to a stored, logic “One” and the less conductive state to a stored, logic “Zero”, or vice versa).

With the above-mentioned Phase Change Memory Cell 1, e.g. an appropriate chalcogenide compound (e.g. a Ge—Sb—Te or an Ag—In—Sb—Te compound) may be used as an “active” material for the above-mentioned material layer 3.

The chalcogenide compound material may be placed in an amorphous, i.e. relatively weakly conductive, or in a crystalline, i.e. relatively strongly conductive, state by means of appropriate switching processes (wherein e.g. the relatively strongly conductive state may correspond to a stored, logic “One” and the relatively weakly conductive state may correspond to a stored, logic “Zero”, or vice versa).

Phase Change Memory Cells are, for instance, known from G. Wicker, Nonvolatile, High Density, High Performance Phase Change Memory, SPIE Conference on Electronics and Structures for MEMS, Vol. 3891, Queensland, 2, 1999, and e.g. from Y. N. Hwang et al., Completely CMOS Compatible Phase Change Nonvolatile RAM Using NMOS Cell Transistors, IEEE Proceedings of the Nonvolatile Semiconductor Memory Workshop, Monterey, 91, 2003, S. Lai et al., OUM-a 180 nm nonvolatile memory cell element technology for stand alone and embedded applications, IEDM 2001, etc.

As results further from FIG. 1, a heating material layer 5—which has e.g. a relatively high resistance—surrounded by an appropriate insulating layer 4 may—optionally—be provided with the Phase Change Memory Cells 1 below the active material layer 3 and above the lower electrode 2b.

In order to achieve, with the memory cell 1, a change from an amorphous, i.e. relatively weakly conductive state of the “active” material, to a crystalline, i.e. relatively strongly conductive state, an appropriate heating current pulse may be applied at the electrodes 2a, 2b, resulting in that the heating material layer 5 and adjacent regions of the active material layer 3 are correspondingly heated—beyond the crystallization temperature of the active material—, which results in a crystallization of the corresponding regions of the active material layer 3 (“writing process”).

A change of state of the corresponding regions of the active material layer 3 from a crystalline, i.e. relatively strongly conductive state, to an amorphous, i.e. relatively weakly conductive state, may, for instance, be achieved in that—again by applying an appropriate heating current pulse at the electrodes 2a, 2b and the resulting heating of the heating material layer 5 and of corresponding regions of the active material layer 3—the corresponding regions of the active material layer 3 are heated beyond the melting temperature and are subsequently “quenched” to a crystalline state by quick cooling (“deleting process”).

To achieve a correspondingly quick heating of the corresponding regions of the active material layer 3 beyond the crystallization or melting temperature, respectively, relatively high currents may be necessary.

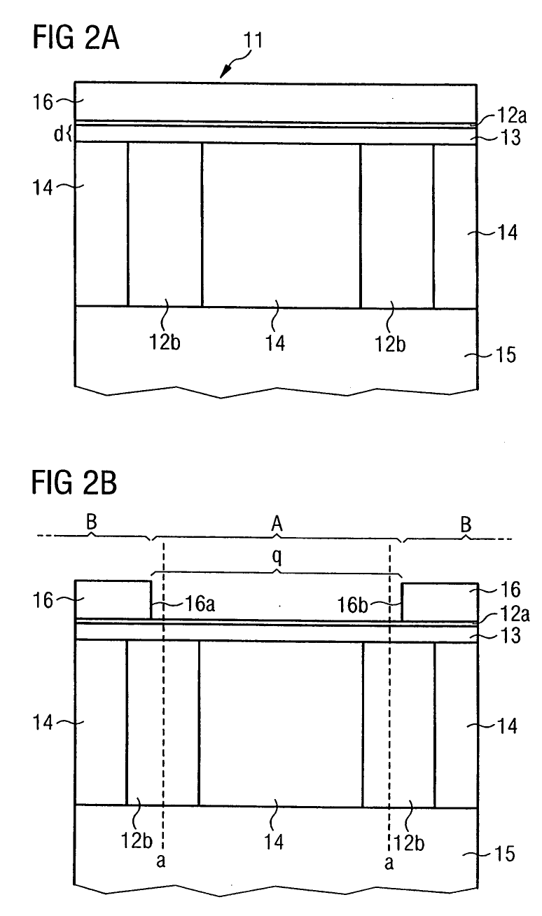

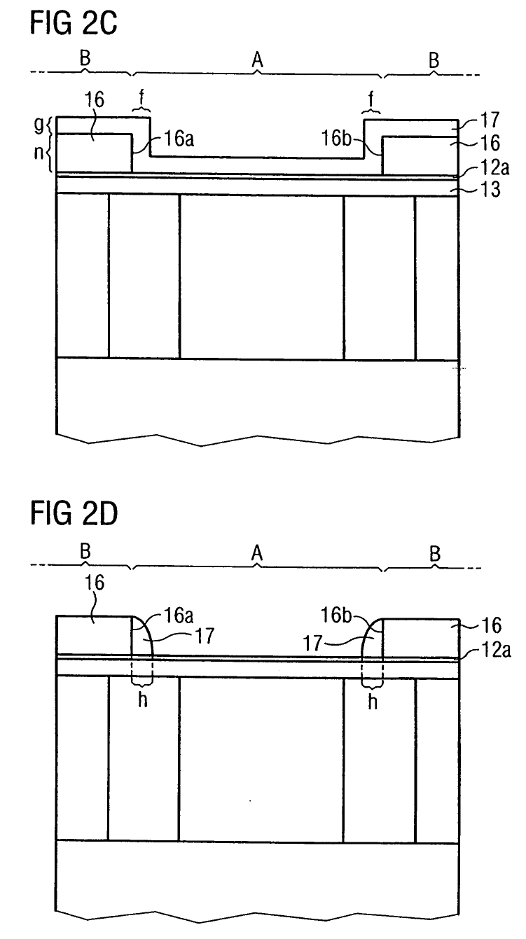

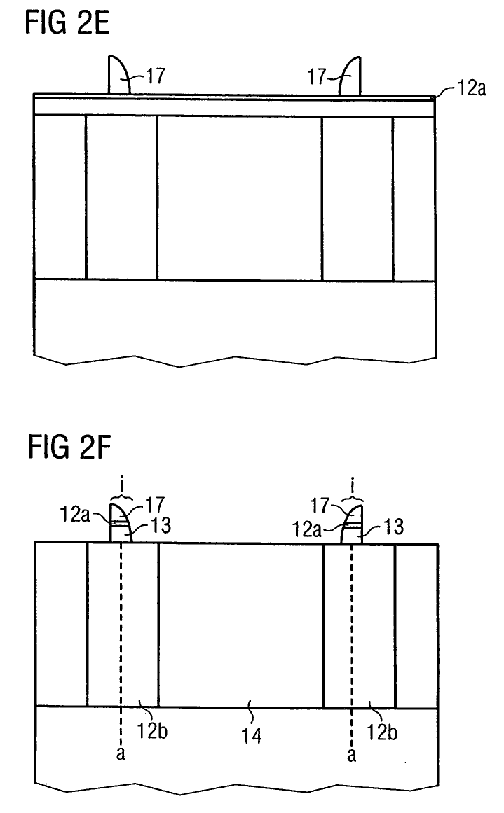

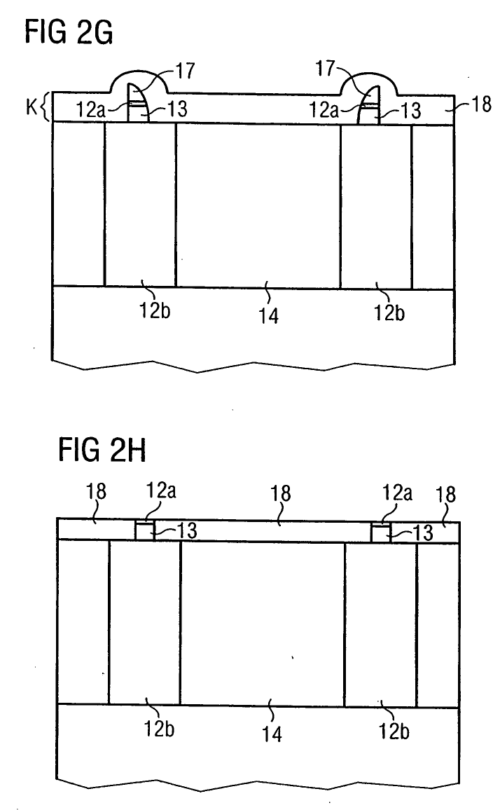

FIG. 2a shows a schematic representation of resistively switching memory cells 11 according to an embodiment of the present invention during a first phase of the production of the memory cells 11.

The memory cells 11 may—as will be explained in more detail in the following—in particular be e.g. Phase Change Memory Cells 11.

As results from FIG. 2a, a corresponding, “active” material layer 13 is positioned between two appropriate metal electrodes or contacts 12a, 12b (i.e. one anode and one cathode), the production of which will be explained in more detail in the following.

The “active” material layer 13 may—in the finished state of the cells 11 (and as will be explained in more detail below)—be placed in a more or less conductive state by appropriate switching processes (in particular in an amorphous, i.e. relatively weakly conductive, or a crystalline, i.e. relatively strongly conductive state, wherein e.g. the more conductive state corresponds to a stored, logic “One” and the less conductive state corresponds to a stored, logic “Zero”, or vice versa).

An appropriate chalcogenide compound (e.g. a Ge—Sb—Te or an Ag—In—Sb—Te compound, etc.), or any other suitable phase change material may, for instance, be used as an “active” material for the above-mentioned material layer 13.

As a material for the upper metal electrode or the upper contact 12a, respectively, TiN, TiSiN, TiAIN, TaSiN, or TiW, etc. may, for instance, be used, or e.g. tungsten, or any other, suitable electrode material.

The lower metal electrode or the lower contact 12b, respectively, may, for instance, be made of tungsten (or e.g. of any other, suitable electrode material).

As results in particular from the representation according to FIG. 3, each of the lower contacts 12b is—in the finished state of the memory cells 11—assigned to a corresponding individual memory cell 21a, 21b, respectively.

The lower contacts 12b of the memory cells 11 are separated from one another by an appropriate insulating layer 14 positioned between the lower contacts 12b (and surrounding the lower contacts 12b laterally).

The insulating layer 14 may, for instance, consist of SiO2, or of any other, suitable insulating material.

Again referring to FIG. 2a, a substrate layer 15, which may, for instance, be made of silicon, is positioned below the memory cells 11 (or below the lower contacts 12b, respectively, and the insulating layer 14 (directly adjacent to the lower limiting regions of the lower contacts 12b positioned in the same plane, and the insulating layer 14)).

In the substrate layer 15, corresponding switching elements, in particular transistors—that control the finished individual memory cells 21a, 21b, in particular provide the heating currents necessary for writing and deleting the individual memory cells 21a, 21b—are arranged, and e.g. corresponding sense amplifiers that read out the data stored in the individual memory cells 21a, 21b, etc.

As will be explained in more detail below, relatively low heating currents may be used with the memory cells 21a, 21b according to FIGS. 2a to 4, in particular heating currents smaller than e.g. 130 μA or e.g. 100 μA, in particular smaller than 80 μA or 60 μA, etc., so that a corresponding individual memory cell 21a, 21b can be controlled by one single, assigned switching element that provides the appropriate heating current (and that comprises e.g. only one single, or two cooperating, oppositely inverse transistors, or an appropriately switched individual diode) (in particular by one transistor or one diode or by transistors with correspondingly small (minimal) structure size).

As results further from FIG. 2a, the active material layer 13—which has a regular thickness d of e.g. <150 nm, in particular e.g. <100 nm (or e.g. <60 nm or <30 nm)—extends (during the phase of production of the memory cell 11 illustrated there) initially in the form of a continuous, horizontal, plane layer above a plurality of lower electrodes or lower contacts 12b of the memory cells 11, said lower electrodes or lower contacts 12b being positioned side by side (and being assigned to different individual memory cells 21a, 21b to be produced), and above the above-mentioned insulating layer 14.

As results also from FIG. 2a, the material layer provided above the active material layer 13 and used for the production of the upper metal electrodes or the upper contacts 12a, respectively, extends—correspondingly—initially (in the phase illustrated in FIG. 2a) also in the form of a continuous, horizontal, plane layer above the above-mentioned plurality of lower electrodes or lower contacts 12b, respectively, of the memory cells 11, the lower electrodes or lower contacts 12b being positioned side by side (and being assigned to different individual memory cells 21a, 21b to be produced).

Above the material layer used for the production of the upper metal electrodes or the upper contacts 12a, respectively, there is provided a further, plane layer 16, e.g. an appropriate SiO2 layer, as results from FIG. 2a.

As results from FIG. 2a, the lower limiting areas of regions of the active material layer 13 positioned above the insulating layer 14 are directly adjacent to corresponding upper limiting areas of the insulating layer 14.

Furthermore—as is illustrated in FIG. 2a—the lower limiting areas of regions of the active material layer positioned above the lower electrodes or lower contacts 12b, respectively, of the memory cells 11 may be directly adjacent to corresponding upper limiting areas of the contacts 12b (the upper limiting areas of the contacts 12b and of the insulating layer 14 will then be flush).

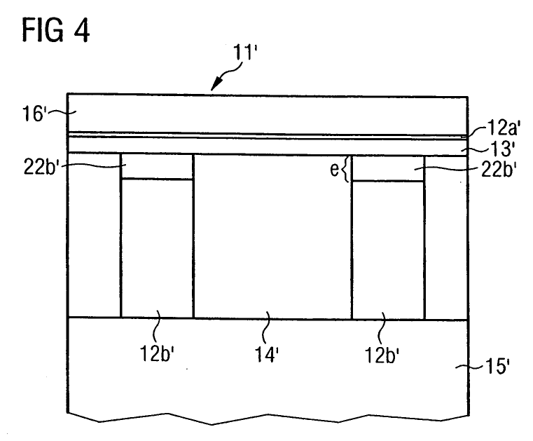

In an alternative embodiment of the invention shown in FIG. 4, appropriate electrodes 22b′ may be provided with memory cells 11′ —which are, otherwise, constructed and produced correspondingly similar to the memory cells 11 illustrated in FIGS. 2a to 2h—between the active material layer 13′ and the contacts 12b′—which include, for instance, tungsten, as has been explained above.

The lower electrodes 22b′—which are positioned between the material layer 13′ and the contacts 12b′ (and are also surrounded by an appropriate insulating layer 14′)—may, for instance, be made of a specific material, e.g.—like the upper electrode 12a′—of TiN, or e.g. of TiSiN, TiAIN, TaSiN, or TiW, etc.

As results from FIG. 4—other than with the embodiment illustrated in FIGS. 2a to 2h—corresponding lower limiting areas of regions of the active material layer 13′ (which are positioned above the lower contacts 12b′ of the memory cells 11′) may then be adjacent to corresponding upper limiting areas of the electrodes 22b′ (and corresponding lower limiting areas of the electrodes 22b′ to corresponding upper limiting areas of the (tungsten) contacts 12b′).

As results also from FIG. 4, the upper limiting areas of the electrodes 22b′ and of the insulating layer 14′ are flush in the embodiment illustrated there.

The electrodes 22b′ may, for instance, be produced by that (tungsten) contacts 12b′—which, correspondingly similar to the embodiment illustrated in FIG. 2a, initially extend upwards to the same extent as the insulating layer 14′—are correspondingly etched back (selectively) to some extent—corresponding to the later thickness e of the electrodes 22b′ (with the surrounding insulating layer 14′ being left correspondingly).

Subsequently, a corresponding material layer—consisting of the material desired for the electrodes 22b′—may be deposited above the—etched—(tungsten) contacts 12b′ (and thus also above the insulating layer 12′).

This material layer is correspondingly—planarly—polished back to the level of the upper limiting area of the insulating layer 12′ (e.g. by means of an appropriate CMP method (CMP=Chemical Mechanical Polishing)), so that the upper limiting areas of the electrodes 22b′ produced this way and of the insulating layer 14′ are flush.

Then (correspondingly similar as with the memory cells illustrated in FIG. 2a), the above-mentioned active material layer 13′ is—above the insulating layer 14′ and the electrodes 22b′—deposited planarly, and there above (again planarly) the material provided for the upper electrodes 12a′, and (again planarly) the layer 16′ corresponding to the layer 16 illustrated in FIG. 2a.

FIG. 2b shows a schematic representation of the memory cells 11 illustrated in FIG. 2a during the next phase of production of the memory cells 11.

In the alternative embodiment of the memory cells 11′ as illustrated in FIG. 4, corresponding process steps are performed—starting out from the state illustrated in FIG. 4—as have been explained with the memory cells 11 by means of FIG. 2b (and FIGS. 2c to 2h). For the sake of avoiding repetitions, a separate representation will be omitted in the following.

As results from FIG. 2b, the material layer 16 that is positioned above the layer from which the upper electrodes 12a are produced, is removed at corresponding regions A and is left at corresponding regions B.

For the selective removal of the material layer 16 at the regions A, any conventional methods may be used due to their relatively large dimensions, e.g. appropriate opto-lithographic methods (where the regions A, but not the regions B (or corresponding regions of a photoresist layer provided above the layer 16) are exposed and then etched away (together with the regions A of the layer 16 positioned below the corresponding, exposed regions of the photoresist layer) (whereupon the photoresist layer is removed again)).

As results from FIG. 2b, a region A of the material layer 16—said region A being positioned between a first electrode 12b (which is assigned to a first, finished individual memory cell 21a (cf. FIG. 3)) and a closest, second electrode 12b (which is assigned to a second, finished individual memory cell 21b (cf. FIG. 3))—is removed, and the next region B that is positioned between the second electrode 12b (which is assigned to the second, finished individual memory cell 21b (cf. FIG. 3)) and a subsequent—not illustrated—third electrode 12b (which is assigned to a third, subsequent individual memory cell 21b) is left, etc., etc.

The respectively removed regions A may—viewed from the top—be e.g. of substantially square (or rectangular) cross-section.

Corresponding to the representation according to FIG. 2b, “before” or “behind” the removed region A illustrated in FIG. 2b (and “before” or “behind” corresponding removed regions positioned “at the left” and “at the right” of the removed region A, further regions may—corresponding to the region A—be removed—(wherein, again, one “non-removed” region is positioned between two “removed” regions, and the corners of the removed regions may each be positioned approximately above a corresponding electrode or individual memory cell, respectively).

With an alternative that is preferred vis-à-vis thereto, the respectively removed regions A are, instead—viewed from the top—linear and extend—in the representation according to FIG. 2b —continuously “forward” or “rearward”, respectively, over a plurality of, in particular over all, individual memory cells 21a positioned in a row, or all electrodes 12b assigned to same, respectively.

The breadth q of the removed regions A is then distinctly smaller than their length.

As results from FIG. 2b, the outer edges 16a, 16b of the —left—regions B of the layer 16 each are positioned above the electrodes 12b (or above the individual memory cells 21a, 21b that have to be produced and that are assigned to same, respectively), in particular substantially above the central axis a of the corresponding electrodes 12b (or are—as will be explained in more detail in the following and as is represented schematically in FIG. 2b —e.g. each displaced by approximately half the breadth of the active material of the—finished—memory cells 21a, 21b to the “left” or to the “right”, respectively (or to the “front” or to the “rear”, respectively) (cf. below)).

Next—as is illustrated schematically in FIG. 2c —a layer 17 is deposited above the regions A and B (or above the—left—regions B of the layer 16 and the—uncovered—regions A of the layer from which the upper electrodes 12a are produced later), the layer 17 consisting of an appropriate spacer material, e.g. SiN or C, etc. The spacer layer 17 may have a substantially constant thickness g and may coat in particular the outer edges 16a, 16b of the—left—region B of the layer 16—to the “right” or to the “left”, respectively (or to the “front” or to the “rear”, respectively) with a material layer having a breadth f that corresponds substantially to the breadth of the active material of the—finished—memory cells 21a, 21b (wherein the breadth f may, for instance, be ≦100 nm, in particular e.g. ≦60 nm, or ≦30 nm (cf. below)).

Advantageously, the spacer layer 17 has a thickness d smaller than the thickness n of the layer 16.

Subsequently—as is illustrated schematically in FIG. 2d—the spacer layer 17 is etched back anisotropically (namely such that the spacer layer 17 is removed completely at the above-mentioned regions B and partially—namely not at the edge (or corner) regions—at the above-mentioned regions A).

The portion of the spacer layer 17 that has been left is positioned—as results from FIG. 2d—directly adjacent “at the right” or “at the left”, respectively (or to the “front” or to the “rear”, respectively) to the outer edges 16a, 16b of the region B of the layer 16 that has been left (and extends—in particular with the above-mentioned, preferred alternative—in the representation according to FIG. 2d linearly continuously “forward” or “rearward” over a plurality, in particular all, individual memory cells 21a positioned in a row, or all electrodes 12b assigned to same, respectively).

As results further from FIG. 2d, the portion of the spacer layer 17 that has been left has a breadth that expands downwardly up to a maximum breadth h, wherein the maximum breadth h of the portion of the spacer layer 17 that has been left corresponds (at the place where the spacer layer 17 contacts the electrode layer 12a) substantially to the breadth of the active material of the—finished—memory cells 21a, 21b (wherein the maximum breadth h of the portion of the spacer layer 17 that has been left may, for instance, be <100 nm, in particular e.g. ≦60 nm or ≦30 nm (cf. below)).

Next (or, alternatively, after the state of the memory cells 11 illustrated in FIG. 2e), method steps that correspond to the above-explained method steps may—in particular with the above-mentioned, preferred alternative—be performed again.

In particular, a continuous (additional) layer may again be deposited above the active material layer 13 or the layer 12a, respectively (and above the (linear) spacer layer 17 that has been left, and possibly above the—left—region B of the layer 16), e.g. an SiO2 layer (corresponding to the layer 16 illustrated in FIG. 2).,

This layer may then—correspondingly similar as illustrated for the layer 16 in FIG. 2b—be structured (wherein corresponding, linear, removed regions of the (additional) layer extend transversely to the created line structure of the layer 16 or the spacer layer 17, respectively, over a plurality of, in particular all individual memory cells 21a, 21b positioned in a row, from the “left” to the “right”).

Subsequently—possibly (alternatively) after a new deposition of a (further) spacer layer—the spacer layer 17 (or the spacer layer 17 and the further spacer layer, respectively) may be etched back anisotropically (as described above with reference to FIG. 2d).

If a further spacer layer is used, it may include the same material as the spacer layer 17, or—preferably—of some other material than the spacer layer 17 (both spacer layers may, for instance, include C or SiN, or one spacer layer of C and the other one of SiN).

Then—as is illustrated in FIG. 2e—the regions B of the layer 16 (or of the additional layer corresponding thereto) that have been left during the foregoing process steps are removed (not, however, the—remaining—portion of the spacer layer(s) 17).

To this end, e.g. an appropriate, selective etching method may be used, for instance, an appropriate wet etching method (e.g. a HF (hydrofluoric acid) wet etching method).

Subsequently, as is illustrated in FIG. 2f, the above-mentioned electrode layer 12a and the active material layer 13 positioned therebelow are removed—with the exception of regions positioned directly below the portions of the spacer layer 17 that have been left, e.g. by means of an appropriate dry etching method.

The electrodes 12a produced thereby—that have been left below the corresponding, remaining portions of the spacer layer 17—and the respective active material layer 13 positioned therebelow—that has been left—may, for instance—corresponding approximately to the breadth (and/or the length) of the spacer layer 17 positioned thereabove—have a breadth (and/or a length) i smaller than or equal to 100 nm, in particular e.g. a breadth (and/or a length) i smaller than or equal to 60 nm or smaller than or equal to 30 nm (i.e. a breadth (or a length) i in the sub-lithographic range).

The electrodes 12a that have been left and the active material layer 13 that has been left (and also the electrodes 12b) may—viewed from the top—be substantially square or rectangular.

The central axes a of the electrodes 12a that have been left and of the portions of the active material layer 13 that have been left may, for instance, lie substantially on the central axes a of the lower contacts or electrodes 12b (or in the vicinity thereof) (the lower electrode 12b having a breadth and/or length bigger than the breadth and/or length of the active layer 13).

Next—as is illustrated schematically in FIG. 2g —a corresponding insulating material layer 18 that may, for instance, include SiO2 or SiN, etc., is deposited above the spacer layer 17 that has been left and above the insulating layer 14—that has been uncovered during the latest process step (and the region of the lower electrode 12b uncovered during the latest process step and surrounding the remaining active material layer 13).

The insulating material layer 18 may have a substantially constant thickness k (corresponding at least to the sum of the thickness of the upper electrode 12a and the active material layer 13). Preferably—alternatively—for deposition of the insulating material layer 18 a partially planarizing deposition method may be used; the thickness of the insulating material layer 18 above the regions 17 will then be less than in the remaining regions.

The layer 18 is then, as is schematically illustrated in FIG. 2h, correspondingly polished back—planarly—roughly up to the height of the upper limiting areas of the upper electrodes 12a (e.g. by means of an appropriate CMP method (CMP =Chemical Mechanical Polishing)), with the remaining portions of the spacer layer 17 being completely removed.

Finally, correspondingly similar as with conventional, known methods, a corresponding, upper metal contact 19a, 19b may be produced for each of the individual memory cells 21a, 21b produced in the above-mentioned manner (and each comprising an upper and a lower electrode 12a, 12b and an active material layer 13 positioned therebetween and embedded into the insulating material layer 18), the upper metal contact 19a, 19b contacting the respective—upper—electrode 12a positioned therebelow (cf. FIG. 3).

In a further alternative embodiment—other than illustrated e.g. in FIGS. 2a and 4—no separate layer used for the later production of the electrodes 12a, 12a′ may, first of all, be provided between the active material layer 13, 13′ and the layer 16, 16′ (the active material layer 13, 13′ will then be directly adjacent to the layer 16, 16′).

After performing the method steps—corresponding to the method steps explained above by means of FIGS. 2a to 2h—the upper limiting area of the active material layer produced this way and embedded in an insulating material layer is flush with the upper limiting area of the insulating material layer.

Subsequently—correspondingly similar as with corresponding conventional, known production methods—a corresponding metal electrode contacting the respective, active material is produced above the active material layer for each of the individual memory cells produced this way.

In order to achieve, with a corresponding individual memory cell 21a, 21b, a change from an amorphous, i.e. relatively weakly conductive state of the corresponding “active” material layer 13, to a crystalline, i.e. relatively strongly conductive state, an appropriate heating current pulse may be applied at the electrodes 12a, 12b by the respectively assigned, above-mentioned switching element (correspondingly similar as with conventional Phase Change Memories), and as explained above with reference to FIG. 1 (cf. also e.g. G. Wicker, Nonvolatile, High Density, High Performance Phase Change Memory, SPIE Conference on Electronics and Structures for MEMS, Vol. 3891, Queensland, 2, 1999, and e.g. Y. N. Hwang et al., Completely CMOS Compatible Phase Change Nonvolatile RAM Using NMOS Cell Transistors, IEEE Proceedings of the Nonvolatile Semiconductor Memory Workshop, Monterey, 91, 2003, S. Lai et al., OUM-a 180 nm nonvolatile memory cell element technology for stand alone and embedded applications, IEDM 2001, etc.)).

The heating current pulse results—since the active material layer 13 has a relatively high resistance—in that the active material layer 13 is correspondingly heated beyond the crystallization temperature of the active material, which may cause a crystallization of the active material layer 13 (“writing process”).

A change of state of the active material layer 13 from a crystalline, i.e. relatively strongly conductive state, to an amorphous, i.e. relatively weakly conductive state, may, for instance, be achieved in that a corresponding heating current pulse is applied at the electrodes 12a, 12b by means of the respectively assigned, above-mentioned switching element, thereby heating the active material layer 13 beyond the melting temperature, and in that the active material layer is subsequently “quenched” to an amorphous state by quick cooling (“deleting process”) (correspondingly similar as with conventional Phase Change Memories).

As results from FIG. 3, the active material layer 13 is—in the finished state of the memory cells 21a, 21b —embedded in the insulating material layer 18 and is in particular—laterally (to the “right”, “left”, “front”, and “rear”)—completely surrounded by the insulating material layer 18.

Due to the focused current flow achieved by the embedding of the active material layer 13 in the insulating material layer 18 (and thus the reduction or prevention, respectively, of parasitic currents occurring outside the melting or crystallization region of the active material), the active material can, in the present embodiments—as has already been mentioned above—, be heated beyond the crystallization or melting temperature, respectively, with partially distinctly lower heating currents than in prior art.

List of reference signs

1 memory cell
2a electrode
2b electrode
3 active material layer
4 insulating layer
5 heating material layer
11 memory cells
11′ memory cells
12a electrode
12a′ electrode
12b electrode
12b′ electrode
13 active material layer
13′ active material layer
14 insulating layer
14′ insulating layer
15 substrate layer
15′ substrate layer
16 layer
16a layer edge
16b layer edge
17 spacer layer
18 insulating material layer
19a contact
19b contact
21a individual memory cell
21b individual memory cell

1. A memory device, comprising an active material adapted to be placed in a substantially conductive state by means of appropriate switching processes, wherein the active material is embedded in electrically insulating material.

2. The memory device according to claim 1, wherein the active material is completely surrounded by electrically insulating material in a lateral direction.

3. The memory device according to claim 1, wherein the memory device has the active material adapted to be placed completely or partially in an amorphous or a crystalline state by means of appropriate switching processes.

4. The memory device according to claim 3, wherein the extension of volume of the active material affected by the phase change is limited by the electrically insulating material.

5. The memory device according to claim 1, wherein the active material has a breadth smaller than or equal to 100 nm.

6. The memory device according to claim 1, wherein the active material has a length smaller than or equal to 100 nm.

7. The memory device according to claim 1, wherein the active material has a thickness smaller than or equal to 100 nm.

8. The memory device according to claim 1, wherein the insulating material comprises SiO2.

9. The memory device according to claim 1, wherein the insulating material comprises SiN.

10. The memory device according to claim 1, wherein the memory device comprising a first electrode adjacent to the active material.

11. The memory device according to claim 1, wherein the memory device comprising a second electrode adjacent to the active material.

12. The memory device according to claim 11, wherein the active material is completely enclosed by the first and second electrodes and the insulating material.

13. The memory device according to claim 10, wherein the first and/or the second electrode is made of TiN, or of TiSiN, TIAIN, TaSiN, or TiW.

14. The memory device according to claim 10, wherein the first and/or second electrode is made of tungsten.

15. The memory device according to claim 11, wherein the first and second electrodes are made of the same material.

16. The memory device according to claim 11, wherein the first and second electrodes are made of different materials.

17. A method for producing a resistively switching memory device, comprising:
(a) depositing a layer above an active material provided for the resistively switching memory device;
(b) structuring the layer;
(c) depositing a spacer layer above the structured layer; and
(d) etching back the spacer layer anisotropically.

18. The method according to claim 17, wherein, in step (d), the spacer layer is removed except in regions adjacent to edge regions of the structured layer.

19. The method according to claim 17, wherein the layer is structured linearly.

20. The method according to claim 17, further comprising:
(e) newly depositing a layer above the active material provided for the resistively switching memory device;
(f) structuring the newly deposited layer; and
(g) etching back the spacer layer anisotropically.

21. The method according to claim 17, further comprising:
(e) newly depositing a layer above the active material provided for the resistively switching memory device;
(f) structuring the newly deposited layer;
(g) depositing a further spacer layer above the newly deposited structured layer;
(h) etching back the spacer layers anisotropically.

22. The method according to claim 20, wherein the newly deposited layer is structured transversely to the line structure of the layer that has been deposited first.

23. The method according to claim 17, further comprising:
depositing a contact material layer above the active material provided for the resistively switching memory device before the layer is deposited above the active material provided for the resistively switching memory device, or above the contact material layer, respectively.
